(19) United States
(12) Patent Application Publication
(10) Pub. No.: US 2004/0073945 A1
(43) Pub. Date: Apr. 15, 2004

(54) DATA RECEPTION DEVICE AND DATA RECEPTION METHOD

(76) Inventor: KEIJI YUZAWA, SAITAMA (JP)

Correspondence Address: LERNER, DAVID, LITTENBERG,, KRUMHOLZ & MENTLIK, 600 SOUTH AVENUE WEST, WESTFIELD, NJ, 07090, US

(21) Appl. No.: 09/035,612

(22) Filed: Mar. 5, 1998

(30) Foreign Application Priority Data
Mar. 13, 1997 (JP) P09-059155

(51) Int. Cl. H04N 7/16; H04N 7/173; G06F 13/00; H04N 5/445; G06F 3/00; G06F 9/24; G06F 15/177; G06F 9/445; G06F 9/00; H03K 19/003; H05K 10/00; H02H 3/05; H04B 1/74; H04L 1/22

(52) U.S. Cl. 725/132; 725/140; 725/50; 714/18; 714/1; 713/2

(57) ABSTRACT

When program data is downloaded through a broadcast wave, the program is prevented from being kept incomplete due to degradation of a reception state. When new program information is detected, a C/N value is observed. It is determined whether the observed C/N value is a specified value or more. If the C/N value is the specified value or more, a program for download control is executed. It is determined whether the download process is ended. The download process is executed until the download process is ended. Since the download process is executed after it is confirmed that the C/N is preferable, a risk that the downloading is interrupted due to degradation of the reception state in the middle of the download process can be avoided.

### BACKGROUND OF THE INVENTION

1. Field of the Invention

The present invention relates to a data reception device and a reception method which are used when a plurality of program data are transmitted by using, e.g., digital satellite broadcast.

2. Description of the Related Art

In recent years, a digital broadcast system which transmits an image signal, an audio signal, or the like by using a communication satellite has been practically used. The present invention can be applied to the digital broadcast system. FIG. 7 shows the outline of a typical digital broadcast system. The program transmission side is constituted by an up-link station, a program provider, and a management system.

Video/audio data from a program provider 101 is supplied to an encoder, multiplexer 103 of MPEG (Moving Pictures Expert Group)2 of an up-link station 102. The video/audio data is compressed in the MPEG2 encoder, multiplexer 103, and the compressed video/audio data is filled in a packet having a length of 188 bytes. A plurality of programs and packets of video/audio data corresponding to the programs are multiplexed to form a transport packet of MPEG2. A large number of transport packets are connected to each other to form a transport stream. The number of transport streams corresponds to the number of transponders mounted on a communication satellite.

The MPEG2 transport stream is supplied to a transmission system 104. In the transmission system 104, processes such as a scramble process for each packet, error correction coding for each packet, and modulation are performed, and a modulated output to a transmission antenna 105. The scramble process is required to realize conditional access used to control the audiovisual quality for each viewer. For example, a pay-per view contract in which only a certain program is watched every paying is made possible. A key for canceling the scramble is supplied from a key management system 106 to the MPEG2 encoder, multiplexer 103, and is inserted into the transport stream as one of packets like video/audio information.

The MPEG2 packets are integrally managed by a program management system 107. The program management system 107 is coupled to the key management system 106 to encode a key for canceling scramble. A client management system 108 is arranged to manage items or the like related to audiovisual contracts. Accounting information is transmitted between the client management system 108 and the house of a viewer through a telephone line 109.

Broadcast radio wave is transmitted from the transmission antenna 105 and received by a reception antenna 111 of each house through a communication satellite 110. A receiver 112 is connected to the reception antenna 111. The receiver 112 is constituted by a tuner for designating a reception transponder, a demodulator, a scramble unit for canceling scramble, a demultiplexer for designating separate packets, a video decoder, an audio decoder, and the like. Decoded video/audio signals are supplied to a television receiver 113.

A key for canceling scramble is encoded and transmitted as relevant information together with video/voice. The key for solving cryptography is stored in an IC card 114 inserted in the receiver 112. Program scrambles which can be solved by a transmission side can be controlled by the transmission side on the basis of the contract information of each reception system. A receiver having a conditional access function is called an IRD (Integrated Receiver/Decoder).

The above digital satellite broadcast system has only just begun to be practically used, and a program for controlling a recent receiver on a reception side may be variably changed. This change generally has an object to provide new services and additional values to clients. Several methods can be effective as countermeasures against the change in program.

For example, when a program ROM built in a receiver is replaced with another one, or the receiver is entirely replaced with another one, a countermeasure against the change in program can be made. When an IC card in which a new program is stored is distributed to a client by using the interface, for an IC card, arranged in the receiver, the new program can be loaded from the IC card. However, when a large number of receivers which have been arranged, it is difficult to replace the ROMs of the receivers and collect the receivers. In addition, a method of distributing IC cards requires high cost. Since each IC card has a relatively small memory capacity, the IC card cannot easily store a program.

As a method of solving the above problem, the following method is provided. That is, latest program information is received from a transmission side as broadcast wave, and this program is loaded on a receiver on a reception side. More specifically, program data is inserted into a stream transmitted by satellite broadcast using, e.g., the MPEG2 system, and the program data is downloaded on the receiver side. The downloaded program data is temporarily written in, e.g., a RAM built in the receiver, and the program data is transferred from the RAM to a flash memory, thereby updating the program.

When program data to be written is divided into small units (e.g., 64 kbytes), and a writing process is performed every unit, the capacity of the RAM for temporarily storing a program is reduced. With respect to the flash memory, an old program data is temporality erased, and new program data is written in a portion where the program data is erased, so that the capacity of the flash memory is reduced.

The above method for a program data updating process has the following problem. That is, when an updating process is started, both old and new programs are kept incomplete until the entire storage area of a flash memory to be updated is correctly updated.

In a process of updating a large part (e.g., several Mbytes) of program data, an amount of program data increases, and a long reception time, e.g., about several minutes to several tens minutes, is required for the updating process. Therefore, due to degradation of radio wave conditions caused by rain or the like during a download process of the program data, a risk that the program data cannot be partially acquired arises. In this case, the download process is interrupted until the radio wave conditions are recovered.

As described above, when a program updating operation is started when the radio wave state is unstable, due to degradation of the radio wave state during the updating operation, the updating operation cannot easily continue. A problem that downloading for the program is not completed until the radio wave state is recovered arise. in the state wherein the program is not completed, the receiver cannot be correctly operated.

### SUMMARY OF THE INVENTION

Therefore, it is an object of the present invention to provide a data reception device and a reception method which can avoid a risk that a program is kept incomplete by interruption of an updating operation.

In order to the above problems, the present invention provides a data reception device designed to receive multiplexed digital data, comprising:

means for extracting required data of the received data to store the required data;

means for executing the stored data as a program for unit control; and

means for detecting the quality of a reception state, characterized in that a data storing operation is not performed when the reception state is no good.

The present invention also provides a data reception method designed to receive multiplexed digital data, comprising:

the step of extracting required data of the received data to store the required data;

the step of executing the stored data as a program for unit control; and

the step of detecting the quality of a reception state,

characterized in that a data storing operation is not performed when the reception state is no good.

Since a program updating operation is not performed when the reception state is no good, the following situation can be prevented. That is, the updating process is interrupted, the program is kept incomplete, and, in the meantime, the receiver cannot be operated.

### BRIEF DESCRIPTION OF THE DRAWINGS

FIG. 1 is a block diagram showing the arrangement of an embodiment of the present invention.

FIG. 2 is a flow chart showing an example of a control operation in the embodiment of the present invention.

FIG. 3 is a flow chart showing another example of a control operation in the embodiment of the present invention.

FIG. 4 is a block diagram showing an arrangement related to observation of a reception state in the embodiment of the present invention.

FIG. 5 is a schematic diagram showing a theoretical curve representing the relationship between a bit error rate and a C/N and a curve changed depending on an AGC reference voltage.

FIG. 6 is a schematic diagram showing an example of a form in which an AGC reference voltage is changed depending on a bit error rate.

FIG. 7 is a schematic diagram showing the outline of a typical digital broadcast system.

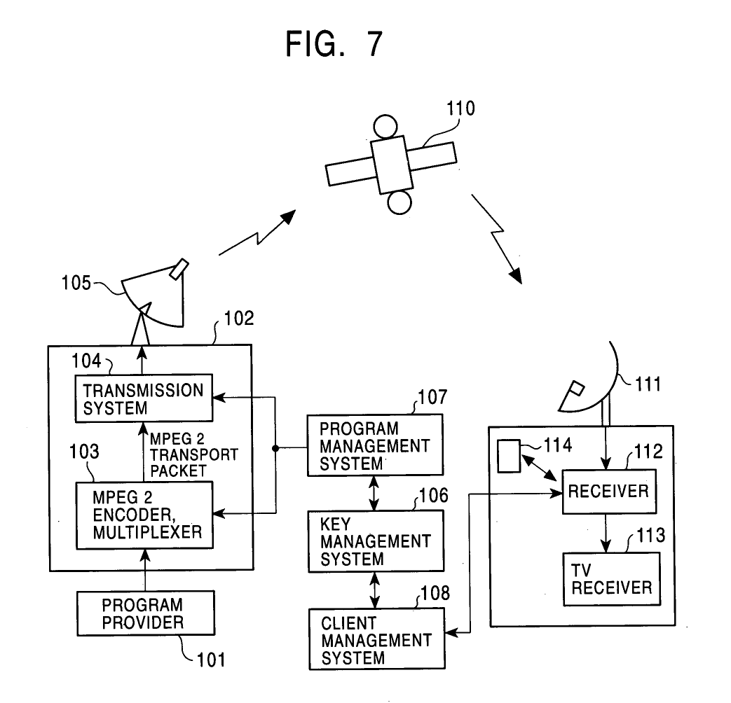

### DESCRIPTION OF THE PREFERRED EMBODIMENT

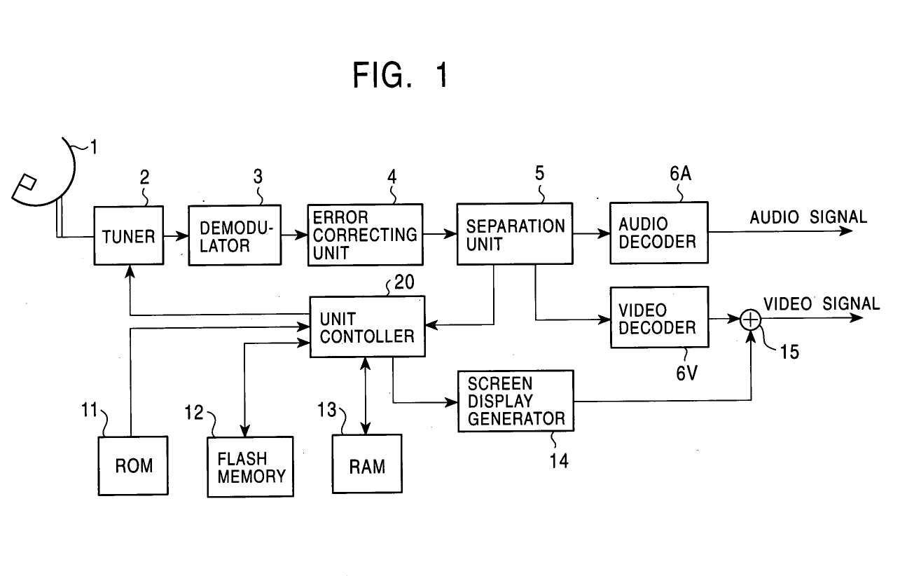

An embodiment of the present invention will be described below with reference to the drawings. FIG. 1 is a block diagram showing an embodiment of the present invention. A reception antenna indicated by 1 receives a radio wave from a communication satellite (or broadcast satellite). A converter connected to the reception antenna 1 down-converts the received signal into the first IF (Intermediate Frequency) signal having a predetermined frequency to output the signal to a tuner 2.

In the tuner 2, a reception channel (i.g., a reception transponder) set by a user is selected to generate the second IF signal. The second IF signal is supplied to a demodulator 3, and, e.g., demodulation of QPSK is performed. A demodulated output from the demodulator 3 is supplied to an error correcting unit 4. The error correcting unit 4 uses an error correction code, e.g., the Read-Solomon code or the Viterbi decode, to correct an error generated during transmission. An output (transport stream) from the error correcting unit 4 is supplied to a separation unit 5. Descramble for canceling scramble is performed between the error correcting unit 4 and the separation unit 5.

In the separation unit 5, the packet of a desired channel is separated from the transport stream, and the packet is separated into video data, audio data, and additional data (including program information) on the basis of information of a header portion. The video data is decoded by a video decoder 6V to generate a received video signal. The audio data is decoded by an audio decoder 6A to generate a received audio signal. The additional data separated by the separation unit 5 is supplied to a unit controller 10. An adder 15 adds a display signal to the decoded video data, and an output video signal from the adder 15 is displayed on a display (not shown). Similarly, the decoded audio signal is amplified by, e.g., an amplifier, to be output from a loudspeaker (not shown).

The unit controller 10 is to control the operation of the entire receiver, and is constituted by a microcomputer. The tuner 2, a ROM 11, a flash memory 12, a RAM 13, and a screen display generator 14 are coupled to. the unit controller 10. In addition, bit error rate information is supplied from the error correcting unit 4 to the unit controller 10. Since a bit error rate is correlated to a C/N, the unit controller 10 can know a radio wave state (C/N) on the basis of the bit error rate information. An indication representing the degree of C/N can be displayed on the tube surface of a display by the unit controller 10 and the screen display generator 14.

Although not shown, a modem is connected to the unit controller 10 to transmit accounting information to a management system through a telephone line. In addition, an operation unit (keys on a front panel, a pointing device such as a tube-surface display or a mouse, a remote control system, and the like) for a user is also coupled to the unit controller 10. This operation unit includes keys and buttons operated in a downloading operation.

In the ROM 11, a program for download control is stored. The download control performed by the unit controller 10 is made on the basis of the program stored in the ROM 11. A program for general operation control is stored in the flash memory 12. The general operation control (i.e., control except for the download control) performed by the unit controller 10 is made on the basis of the program stored in the flash memory 12. The RAM 13 is used as a temporary storage unit used when the flash memory 12 is updated. The screen display generator 14 generates various display signals under the control of the unit controller 10. This display signal includes a signal for displaying the C/N. The display signal is supplied to the adder 15 to be superposed on the decoded video signal.

The program data for controlling the above receiver is transmitted as a broadcast wave, and the program data is received and downloaded in the flash memory 12 through the RAM 13, so that the program for controlling the receiver can be changed.

When the downloading is performed, the program data separated by the separation unit 5 is written in the RAM 13 in updating units (e.g., 64 kbytes). The RAM 13 holds the data until the updating process of one updating unit of the flash memory 12 is ended. The program data of one updating unit is read from the RAM 13, and then written in the flash memory 12. Until an updating process for a program to be downloaded is completed, the process of one updating unit is repeated.

In the MPEG2, a data stream is divided into units called packets to be transmitted. One packet is constituted by a 4-byte header portion and 184-byte pay-load portion, and has a size of 188 bytes. In the header portion, information of packets and information representing the relationship between the packets are stored. A PID serving as identification information of the packets is added to the header portion. More specifically, the same PID is added to transport packets generated by the same data stream. The destination (the video decoder 6V, the audio decoder 6A, or the unit controller 10) of the packets is designated by the PID.

For example, program data is transmitted according to a private section ruled by Systems (ISO 13818-1). A section in which the program data is stored is called a load section. In the section for program transmission, in addition to the program data, information for identifying the maker and model of a receiver, an ID representing the version of the program data, information representing a transponder to which required program data is transmitted, information of the length of the program data, and the like are stored. Therefore, the receiver can select required program data from these pieces of information to load it. More specifically, a transponder to which proper program data is transmitted is designated, and, on the basis of the maker, ID of model, version ID, and the like of the receiver, it is checked whether the program data transmitted from the transponder is proper or not. If the program data is proper, the program data is used as an object to be downloaded.

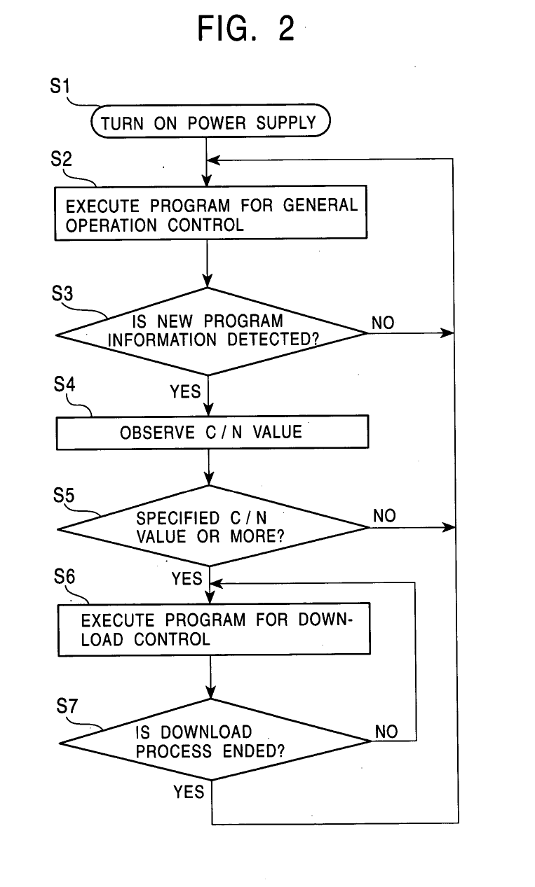

In the present invention, before the download process is started, it is determined depending on the quality of a reception state whether the download process is performed. Such a process will be described below with reference to the flow chart shown in FIG. 2. When a power supply is turned on first (step S1), a program for general operation control is executed (step S2). An example of the general operation is a reception channel switching operation.

In step S3, it is determined whether new program information is detected or not in the received signal. The transmission side repetitively transmits a plurality of programs depending on the maker, model, and version of the receiver. The determination in step S3 is performed with reference to the designation of the transponder, the maker, the ID of model, and the version ID which are included in the above transport stream. If new program information is detected, a C/N is observed for a predetermined period of time (e.g., about 10 seconds), and the average value of the C/N is calculated within the predetermined period of time (step S4).

It is determined whether the average value of the calculated C/N is a specified value or more (step S5). If YES in step S5, the flow shifts to step. S6 to execute the program for download control. If NO in step S5, the flow returns to step S2. For example, when a threshold C/N is 6 dB, if the average value of the C/N is smaller than 10 dB, downloading is not performed.

It is determined in step S7 whether the download process has been ended or not. When all the programs to be updated are updated, the download process is ended. As the programs, a basic program having a routine for performing a basic process such as a boot routine and an application program for actually providing services are known. One of the programs may be downloaded, or both the programs may be downloaded. If it is determined in step S7 that the download process has been ended, the flow returns to step S2. If NO in step S7, the operations in steps S6 and S7 are repeated until the download process is ended.

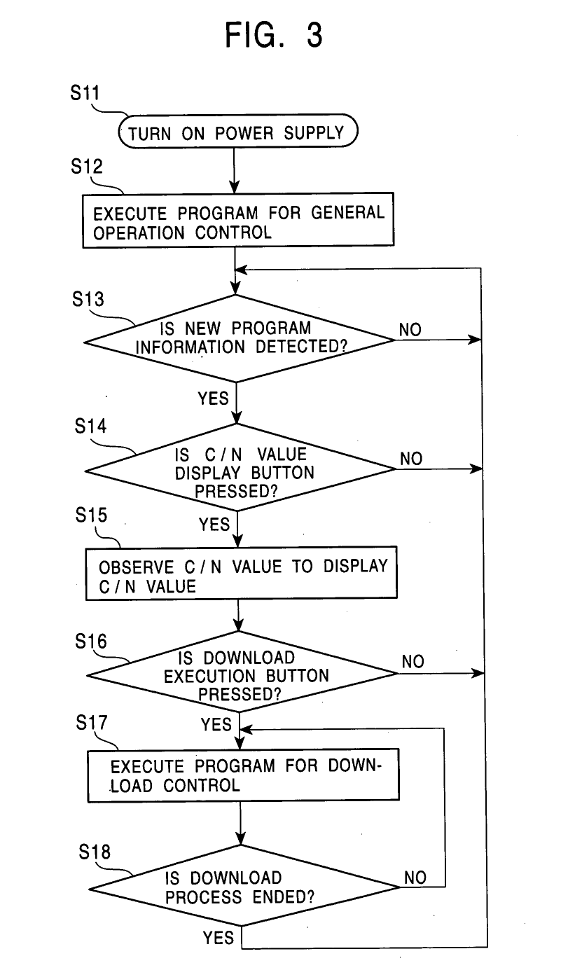

In the processes shown in FIG. 2, the download process is automatically performed when the C/N value, e.g., the average value is a specified value or more. However, the C/N value may be displayed on the tube surface of the display, so that a viewer sees this display to select whether the download process is started. The flow of these processes performed in this case is show in the flow chart in FIG. 3. Steps S11 (turning on of the power supply), S12 (execution of the program for general operation control, and S13 (determination whether new program information is detected) in FIG. 3 are the same as those in steps S1, S2, and S3 in FIG. 2.

It is determined in step S14 whether a viewer presses a C/N value display button. For example, a button for designating the display of a C/N value, a button for designating execution of downloading, a C/N value display for displaying a C/N value as a number, and a program display for displaying a progress state of the download process as a percentage can be displayed on the tube surface of the display. Therefore, an actual operation for pressing a button is performed by movement of a cursor and clicking of a mouse. As a matter of course, command buttons or the like for remote control may be operated in place of the buttons displayed on the tube surface. When the C/N value display button is not pressed, the flow shifts to step S12. When this button is pressed, the C/N value is observed to be displayed (step S15).

The C/N value is also displayed on the tube surface. The C/N value is displayed with, e.g., a two-digit number. In this case, the C/N value calculated on the basis of a bit error rate is directly displayed, or a number obtained by replacing the C/N value is displayed such that a viewer can easily understand the radio wave state. Observation of the C/N value and display thereof are also used as antenna levels used when the direction of the antenna is adjusted.

A viewer sees the display of the C/N value to determine whether downloading is performed. If downloading is performed, the download execution button is pressed. In the manual of the receiver or the display on the tube surface, the relationship between the displayed C/N value and the reliability of completion of the download process is explained, and the viewer refers to the relationship to determined whether the download process is performed. When there is time enough to permit interruption of the download process caused by degradation of the radio wave state, even if the display of the C/N value is not too preferable, the download execution button is pressed. On the other hand, when time for the download process is avoided from being elongated by the interruption of the download process, the execution button is pressed after it is confirmed that the display of the C/N value is preferable. Even if the downloading is interrupted, when the radio wave state is improved thereafter, the download process can be performed from the continuation of the program data which has been downloaded.

In step S16, it is determined whether the download execution button is pressed. If the download execution button is pressed, execution of the program for download control (step S17) is performed to check whether the download process is ended (step S18). The processes in steps S17 and S18 are the same as those in steps S6 and S7 in FIG. 2.

According to the control method shown in the flow chart in FIG. 3, after the degree of risk that a download process is interrupted is notified to a viewer, the viewer is caused to select whether the download process is started. Although only one of the control method shown in FIG. 2 and the control method shown in FIG. 3 is satisfactorily used, a viewer may select one of the. control methods which can be active.

One example of a method of calculating a C/N by using a bit error rate of the error correcting unit 4 will be described below. As one method, a method in which errors detected in a modulation output are counted to display the count value can be used. According to this method, when the C/N is preferable, time in which one error can be observed is too long. For example, when the C/N is 16 dB, a bit error rate (theoretical value) is 1×10⁻⁸, and time required to observe one error is 2.5 sec. When the C/N is 17 dB, a bit error rate (theoretical value) is 1.4×10⁻¹, and time required to observe one error is 179 sec. When the C/N is 18 dB, the bit error rate (theoretical value) is 8×10⁻²³, and time required to observe one error is 8.7 hours.

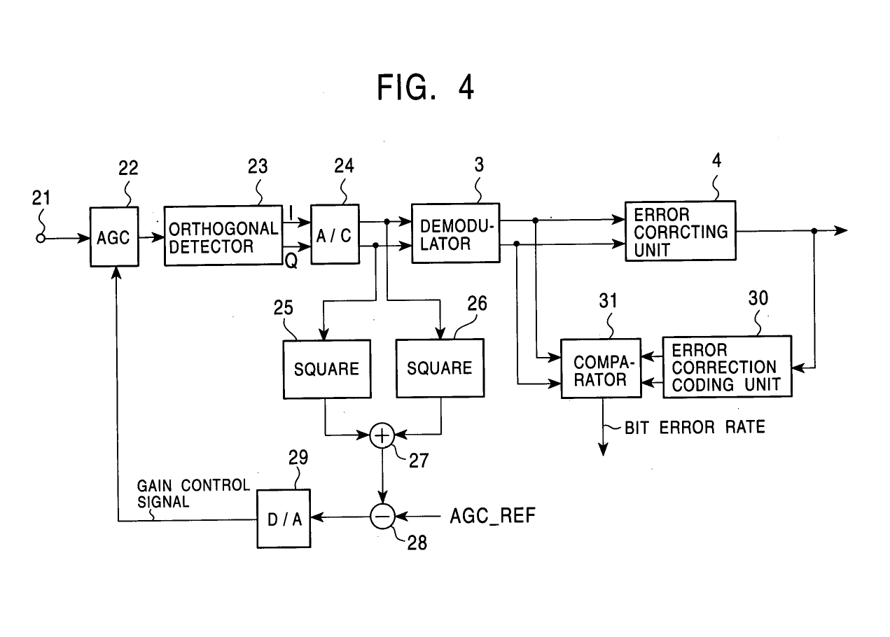

The present applicant proposes a C/N value display device which can solve the problem. The display device will be described below with reference to FIG. 4. The same reference numerals as in FIG. 1 denote the same parts in FIG. 4. Referring to FIG. 4, an IF signal from a tuner is supplied to an input terminal indicated by 21, and a gain is controlled by an AGC amplifier 22. A gain control signal for the AGC amplifier is generated from the output of a D/A converter 29.

An output signal from the AGC amplifier 22 is supplied to an orthogonal detector 23. The orthogonal detector 23 orthogonally detects the output signal from the AGC amplifier 22 to generate analog-base band signals (called an I signal and a Q signal) along an I axis and a Q axis. The I signal and the Q signal are converted into digital signals by an A/D converter 24. The digitized I signal and the digitized Q signal are demodulated by a QPSK demodulator 3. A demodulated signal is supplied to an error correcting unit 4 to perform error correction.

The digitized I signal and the digitized Q signal from the A/D converter 24 are supplied to square-law arithmetic units 25 and 26, respectively. An adder 27 adds outputs from the square-law arithmetic units 25 and 26 to each other. An output from the adder 27 is supplied to a subtractor 28 to be subtracted from an AGC reference voltage (AGC_REF) from the unit controller 10. An output signal from the subtractor 28 is supplied to the D/A converter 29. A gain control signal from the D/A converter 29 is supplied to the AGC amplifier 22.

The gain of the AGC amplifier 22 is feedback-controlled such that the sum of squares of the I signal and the Q signal output from the A/D converter 24 is equal to the AGC reference voltage. Therefore, when the AGC reference voltage is changed, the amplitude of an input of the A/D converter 24 is larger or smaller than a proper value. For example, when the AGC reference voltage is decreased, the amplitude of the input of the A/D converter 24 is made smaller than the proper value.

In addition, the data subjected to error correction and output from the error correcting unit is supplied to an error correction coding unit 30. The error correction coding unit 30 performs error correction coding again. An output from the error correction coding unit 30 is supplied to a comparator 31 for collation. Data which is not subjected to error correction is supplied to the comparator 31. Therefore, the comparator 31 can detect an incoincidence bit as an error bit by collation. The error bit detected as described above is supplied from the comparator 31 to the unit controller 10 as a bit error rate.

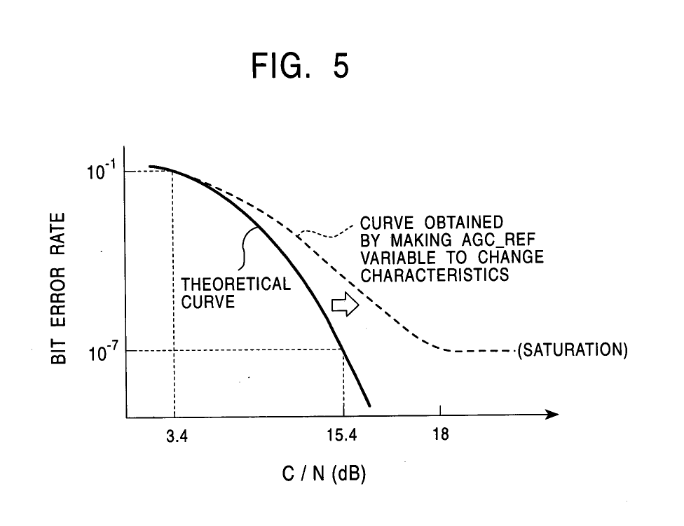

A solid curve in FIG. 5 indicates the relationship (theoretical value) between a C/N and a bit error rate. As is apparent from FIG. 5, the C/N and the bit error rate are correlated to each other. However, as described above, when a transmission rate is represented by R (bps), and the bit error rate is represented by E, time required to detect one error is represented by 1/(R·E) [sec]. When the C/N is preferable, the time becomes long disadvantageously.

According to the value of the bit error rate received by the unit controller 10, as indicated by a broken line in FIG. 5, (AGC_REF) is made variable to change the characteristics. That is, when the C/N is high, noise is equivalently added to apparently decrease the C/N. More specifically, as the bit error rate decreases, the level of the AGC_REF is decreased, the gain of the AGC amplifier 22 is decreased (the input amplitude value of the A/D converter 24 is made smaller than the proper value), and quantization noise is increased, thereby apparently decrease the C/N.

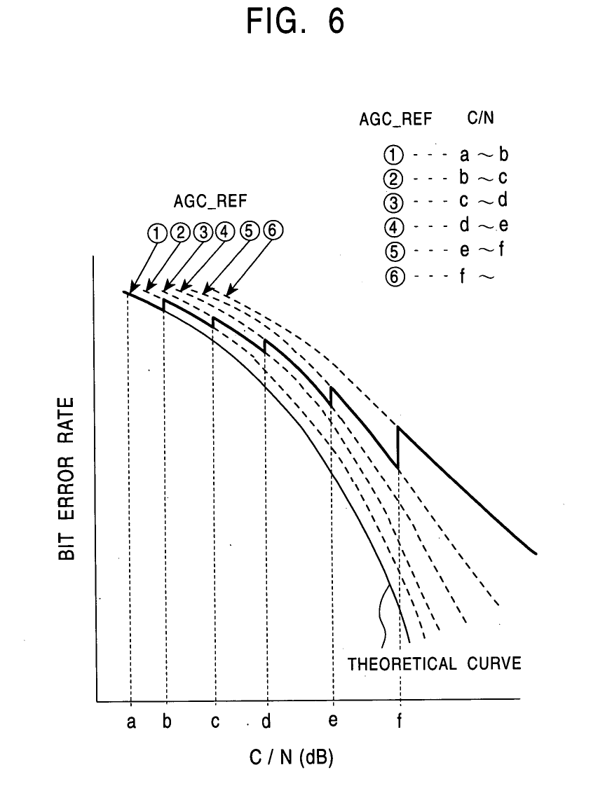

FIG. 6 shows one form in which the AGC_REF is changed depending on a bit error rate. In FIG. 6, circle 1 denotes a theoretical curve, and circle 2 to circle 6 denote curves obtained by shifting the theoretical curve circle 1 in the right direction on the drawing. The shift in the right direction is an operation for decreasing the AGC_REC to apparently decrease a C/N. As the C/N increases, a selected curve is sequentially switched to circle 2, circle 3, circle 4, circle 5, and circle 6. With this process, as shown in FIG. 5, the C/Ns corresponding to the bit error rates of 10⁻¹ to 10⁻⁷ are converted from (3.4 dB to 15.4 dB) (theoretical values) to (3.4 dB to 18 dB). In addition, the bit error rate is designed to be saturated up to 10⁻⁷. According to the above method, the range in which a C/N can be displayed by a bit error rate can be increased.

Observation of a C/N based on a bit error rate is one method of checking the quality of a reception state. A method such as a method of referring to the level of a gain control signal from an AGC amplifier may also be used.

As has been described above, according to the present invention, the following risk can be avoided. That is, when a download process is interrupted by degradation of a radio wave state caused by rain or the like, a program is kept incomplete.

Furthermore, according to the present invention, after a risk that the program may be kept incomplete is notified to a viewer, the viewer can selectively perform a download process.

What is claimed is:

1. A data reception device designed to receive multiplexed digital data, comprising:
means for extracting required data of the received data to store the required data;
means for executing the stored data as a program for unit control; and
means for detecting the quality of a reception state,
characterized in that a data storing operation is not performed when the reception state is no good.

2. A data reception device according to claim 1, characterized in that a data storing operation is automatically performed when the reception state is good.

3. A data reception device according to claim 1, further comprising display means for displaying the quality of the reception state and designation means for designating whether the storing operation is performed or not, and characterized in that the data storing operation is performed in response to designation of said designation means.

4. A data reception device according to claim 1, characterized in that multiplexed digital data transmitted by digital television broadcast is received.

5. A data reception method designed to receive multiplexed digital data, comprising:
the step of extracting required data of the received data to store the required data;
the step executing the stored data as a program for unit control; and
the step of detecting the quality of a reception state,
characterized in that a data storing operation is not performed when the reception state is no good.

6. A data reception method according to claim 5, characterized in that a data storing operation is automatically performed when the reception state is good.

7. A data reception method according to claim 5, further comprising the step of displaying the quality of the reception state and the step of designating whether the storing operation is performed or not, and characterized in that the data storing operation is performed in response to designation of said designation means.

8. A data reception method according to claim 5, characterized in that multiplexed digital data transmitted by digital television broadcast is received.
